(19) United States
(12) Patent Application Publication
(10) Pub. No.: US 2011/0019349 A1
(43) Pub. Date: Jan. 27, 2011

(54) Junction Box for Solar Modules and Method for the Mounting thereof on said Modules

(76) Inventor: Roland Pfeffer, Leutkirch (DE)

Correspondence Address: BOHAN MATHERS, PO BOX 17707, PORTLAND, ME, 04112-8707, US

(21) Appl. No.: 12/922,081

(22) PCT Filed: Mar. 11, 2009
(86) PCT No.: PCT/DE2009/000331

§ 371 Date: Sep. 10, 2010

(30) Foreign Application Priority Data
Mar. 13, 2008 (DE) 10 2008 013 930.0
May 6, 2008 (DE) 10 2008 022 297.6

(51) Int. Cl. H05K 5/00

(52) U.S. Cl. 361/679.01

(57) ABSTRACT

A junction box for mounting on solar modules is disclosed. The junction box enables fully automatic mounting on the solar module, and also automated assembly of the components in the box. The box has a housing with cover. The housing encloses electrical components, such as bypass diodes, and includes connectors that connect to ribbon conductors from the solar module. Within the housing is a positioning block with slots for receiving the ribbon conductors. A hold-down device is also provided in the housing and, when the junction box is mounted on the solar module, the hold-down device presses the ribbon conductors into the slots.

The invention relates to a junction box which permits fully automatic assembly on all commercially available solar modules. The box may also be populated automatically. The method permits the box to be positioned in an uncomplicated manner on the rear of the solar module and connected electrically to the module.

Junction boxes which serve the electrical connection of the individual solar modules of a solar installation are known from the prior art. The junction boxes are affixed to the rear side of the solar modules. Bypass diodes (or power semiconductors with a like function) are assembled in the box, to protect the solar modules against local overheating (hot spots), which occurs when solar modules are partially shaded.

Increasing numbers of solar systems are being installed and the demand for junction boxes is increasing accordingly. Simultaneously, cost pressures are mounting, due to the tariff degression stipulated in the Renewable Energy Sources Act (EEG). Greater demands are also being placed on the quality of the boxes, as ever more powerful solar modules are being installed. Higher reverse currents are encountered in larger solar installations, which demand that the junction boxes provide improved heat dissipation from the bypass diodes.

Junction boxes are currently assembled manually on the solar modules. The junction boxes are also typically populated manually. As time and cost pressures rise for the aforementioned reasons, there is an urgent need to find a method by which both work steps can be performed fully automatically. The targeted automation, however, must not be to the detriment of the quality of the junction boxes. It is particularly important, that no means are employed that impair the heat dissipation from the bypass diodes.

One conceivable option for the fully automatic population of the junction boxes would be to use electronic circuit boards. The use of such boards is out of the question, however, as the high temperature fluctuations occurring in the junction boxes during operation would result in the boards breaking or at least cause contact problems.

The prior art has shown various recent strivings to mount the junction boxes, which have been largely assembled automatically, onto solar modules with reduced effort.

DE 101 54 234 A1, for example, discloses an assembly comprising a panel-like (solar) module and a connector unit (junction box), which are adhesively affixed together and connected electrically by way of connector sections. The connector unit has an electrically conducting stamped grid with ready-formed connector sections. The stamped grid is initially constructed as a single piece, its individual sections being held together bridges. The electronic components and any connector cables are soldered to the stamped grid. The bridges are then removed. The stamped grid is embedded in plastic together with the components, the connector sections remaining exposed. The wires of the solar module are welded or soldered to the connector sections, when the connector unit is mounted on the solar module.

The simplification in mounting and populating the box with components, however, is achieved at the expense of the quality of the connector unit: the bypass diodes are mounted inside the plastic casting and can effectively dissipate the heat they produce only via the connector wires and the stamped grid. The heat dissipation via the connector unit is thus inadequate. Removing the bridges from the stamped grid also requires significant effort. Furthermore, failure of one of the electronic components embedded in the plastic necessitates replacement of the entire connector unit.

### BRIEF SUMMARY OF THE INVENTION

The object of the present invention is thus to overcome the disadvantages of the prior art.

Particularly, the goal is to obtain a junction box which can be fully automatically mounted on all commercially available solar modules. The method should enable in an uncomplicated manner positioning the box on the rear side of the solar module and making the electrical connections.

This object is achieved according to the invention by the characteristic features of claims 1 and 6. Further advantageous embodiments with regard to the junction box are derived from claims 2 to 5.

The starting point is that of a junction box having a housing, in which bypass diodes and necessary electrical connections with connector ends are assembled. The junction box according to the invention has a positioning block, which has receiving slots for the ribbon conductors of the solar modules. The slots correspond in form to that of the ribbon conductors. A hold-down device is mounted on the housing or housing cover, so as to press both the ribbon conductors and the contact clamps that are attached to the connector ends into the slots of the positioning block when the junction box is mounted.

The positioning block has locator pins and the housing has recesses for engaging the locator pins. The housing can thus be simply pushed on for positioning. The pins lock into the housing of the box by means of clips, thereby making a secure connection.

In an embodiment of the junction box, one which can be mounted on the solar module in a particularly fast and uncomplicated manner, the connector ends are fitted with contact clamps which embrace the ribbon conductors when the box is mounted. The electrical contact with the solar module is thus achieved automatically when the housing of the box is adhesively affixed. A hold-down device presses the clamps and the ribbon conductors firmly into the slots of the positioning block. Each of the slots has two recesses to receive the two legs of the contact clamps.

Some manufacturers of solar modules require in their specifications that the connector cables of their modules be soldered or welded with those of the junction boxes. In a further embodiment, the connector ends and the ribbon conductors are inserted into the slots of the positioning block and soldered or welded to each other when the junction box is mounted. A plastic cover is fitted on the inner side of the housing cover and completely covers the positioning block. A hold-down device in the plastic cover presses the connector ends and the ribbon conductors into the slots of the positioning block.

The electrical connectors on the box are stamped conductor tracks that are encased in plastic. It is intended to enclose each of the conductor tracks with two plastic half-shells.

The use of stamped conductor tracks enables fully automatic population of the junction box. In contrast to electronic circuit boards, stamped conductor tracks also withstand high temperature fluctuations.

Following the method according to the invention for mounting of the junction boxes on solar modules, a positioning block is first adhesively affixed to the solar module. The ribbon conductors are inserted in the slots provided for this purpose.

Next, the housing of the junction box is aligned relative to the solar module by inserting the locator pins of the positioning block into the correspondingly formed recesses in the housing.

Finally, the housing is adhesively affixed to the solar module, whereby the housing fully encloses the positioning block. The positioning block is thus protected against influences of the weather. Furthermore, it is ensured that no wires or cables remain exposed, which would otherwise constitute a risk of electric shock in case of accidental contact.

Depending on which embodiment of the junction box is used, the electrical contact between the connector ends and the ribbon conductors of the solar module is achieved either automatically when adhesively affixed by the contact clamps or else by way of soldering or welding in a subsequent step.

The housing of the junction box with contact clamps is mounted with the housing cover closed. The housing is pressed onto the rear side of the solar module when adhesively affixing the housing. The hold-down device causes the contact clamps to be pressed onto the ribbon conductors that are lying in the slots of the positioning block. The clamps embrace the ribbon conductors, guaranteeing a good electrical contact.

When mounting the junction boxes to modules on which soldering or welding of the connector cables is required, the housing of the junction box is initially adhesively affixed to the solar module without the housing cover. The positioning block with the inserted ribbon conductors of the solar module projects through an opening in the base of the housing. The ribbon conductors are soldered or welded to the connector ends of the junction box. Finally, the housing is closed with the cover.

The junction box according to the invention is explained in greater detail below, based on an embodiment. The following figures show:

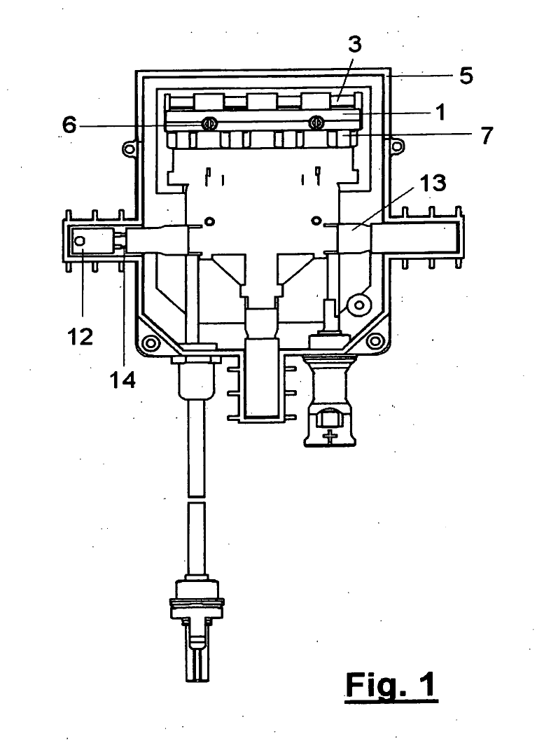

FIG. 1: top plan view of an open junction box with positioning block,

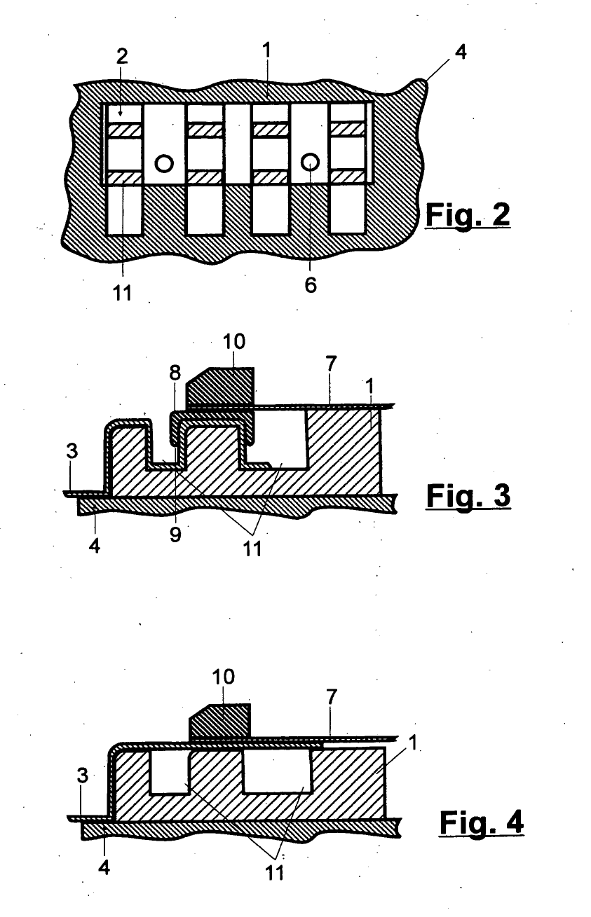

FIG. 2: top plan view of a positioning block mounted on a solar module,

FIG. 3: Cross-section in elevation view of a positioning block with ribbon conductors and connector ends of the junction box, contact clamps making the electrical connection,

FIG. 4: Cross-section in elevation view of a positioning block with ribbon conductors and connector ends of the junction box, soldering or welding making the electrical connection.

The junction box can be mounted fully automatically on all commercially available solar modules 4. Compatibility with the different design forms is achieved by providing individual positioning blocks 1 made of plastic. The electrical contact between the junction box and the solar module 4 is achieved by way of the contact clamps 8. As described above, it is also possible to connect the junction box to the solar module 4 by way of soldering or spot welding.

To connect the junction box to the solar module 4 by way of contact clamps 8, the positioning block 1 is first adhesively affixed to the rear side of the solar module 4 with silicone adhesive or double-sided adhesive tape (see FIGS. 2/3). The ribbon conductors 3 of the module are bent to shape such that they lie in the slots 2 provided for this purpose in the positioning block 1. Subsequently, the closed housing 5 is positioned relative to the solar module 4 by way of the locator pins 6 of the positioning block 1 and the housing 5 is adhesively affixed to the module 4. The pins 6 snap into recesses in the housing 5 by means of clips, achieving a secure mounting connection without placing mechanical load on the solar module. When mounting the housing 5, contact clamps 8 embrace the ribbon conductors 3. The clamps 8 are pressed onto the ribbon conductors 3 by a hold-down device 10 that is integrated into the inner side of the housing cover. The legs 9 of the contact clamps 8 are retained in recesses 11 that are provided in the slots 2 (see FIG. 3).

Similarly, the method of connecting the module 4 by soldering or spot welding begins with adhesively affixing the positioning block 1 and inserting the ribbon conductors 3 into the slots 2 of the positioning block 1. Subsequently, the housing 5 (initially without its cover) is mounted onto the solar module 4 with silicone adhesive or double-sided adhesive tape. The ribbon conductors 3 are soldered or welded to the connector ends 7. The positioning block 1 guarantees sufficient clearance to the rear side of the module and at the same time clearance between the ribbon conductors 3. When the housing 5 is closed, the ribbon conductors 3 are pressed into the slots 2 of the positioning block 1 by the hold-down device 10, which is integrated into the inner side of the housing cover and thereby fixed in place (see FIG. 4). The plastic cover is mounted on the inner side of the housing cover, such that the plastic cover covers the positioning block 1 when the housing cover is closed.

The electrical wiring of the junction box includes stamped copper conductor tracks. With the exception of the connector ends 7, the entire length of the conductor tracks are each fully encased by two profile-like plastic half-shells 13. The half-shells 13 are either integrated into the housing 5 or provided as separate elements. In this way, the junction box easily achieves electrical protection class 2.

The bypass diodes 12 are connected with the stamped conductor tracks by plug-in contacts 14, the conductor tracks acting as the female connector and the connecting wires of the diodes 12 as the male connector. This arrangement permits the replacement of defective bypass diodes 12 without great effort; after unscrewing the housing cover, the diode 12 together with insulation only has to be pulled out of the plug-in contacts and replaced.

### LIST OF REFERENCES USED

1 Positioning block
2 Slot
3 Ribbon conductors
4 Solar module
5 Housing
6 Locator pin
7 Connector end
8 Contact clamp
9 Leg
10 Hold-down device
11 Recess
12 Bypass diode
13 Half-shell
14 Plug-in contact

1. A junction box with a housing (5), in which bypass diodes (12) and necessary electrical connectors are assembled, wherein the electrical connectors have connector ends (7) that serve to connect the ribbon conductors (3) to the solar module (4), characterized in that the connector ends (7) are connected with contact clamps (8) which have two legs (9) and embrace the ribbon conductors (3) when the box is mounted, and the junction box encompasses a positioning block (1) in which receiving slots (2) for the ribbon conductors (3) of the solar module (4) are formed, the form of the receiving slots (2) corresponding to the form of the ribbon conductors (3), each slot (2) being provided with two recesses (11), and a hold-down device (10) being mounted on the housing (5) or housing cover to press the ribbon conductors (3), the connector ends (7) and the clamps (8) into the slots (2) of the positioning block (1), the two legs (9) of the clamps (8) each being received by one of the two recesses (11).

2-6. (canceled)
